(19) United States
(12) Patent Application Publication
(10) Pub. No.: US 2004/0075369 A1
(43) Pub. Date: Apr. 22, 2004

(54) Piezoelectric component

(76) Inventors: Kristian Leo, Burgstetten (DE); Markus Muzic, Murr (DE); Wolfgang Endres, Remshalden (DE); Rudolf Heinz, Renningen (DE); Peter Sprafke, Stuttgart (DE); Alexander Hedrich, Stuttgart (DE); Michael Jupe, Ludwigsburg (DE)

Correspondence Address: KENYON & KENYON, ONE BROADWAY, NEW YORK, NY, 10004, US

(21) Appl. No.: 10/618,972

(22) Filed: Jul. 14, 2003

(30) Foreign Application Priority Data
Jul. 12, 2002 (DE) 1 02 31624.4

(51) Int. Cl. H01L 41/08

(52) U.S. Cl. 310/346

(57) ABSTRACT

A piezoelectric component, including a ceramic actuator having a coating made of an elastomer. The elastomer is a heat conductive elastomer including a filler which is manufactured based upon aluminum dioxide, titanium dioxide, boron nitride, aluminum nitride, silicon carbide and/or preferably silicon dioxide.

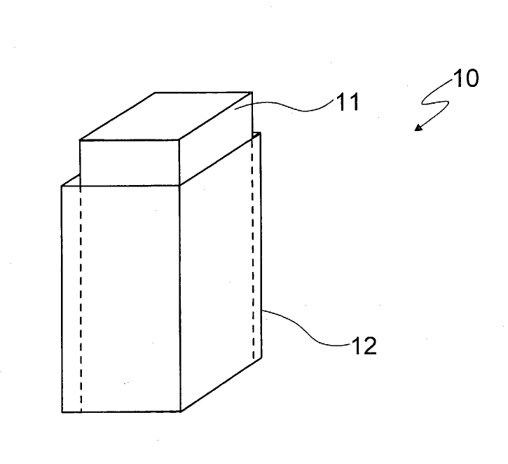

### BACKGROUND INFORMATION

A piezoelectric component is known from German Patent Application No. 198 60 001 and may be utilized as an actuator of a fuel injector of an internal combustion engine, in particular a diesel engine, of a motor vehicle.

The known piezoelectric component, being composed of a monolithic stack of piezoceramic layers and electrode layers situated between them, forming a piezoelectric actuator, is provided on its lateral surface with a protective layer made of plastic; the protective layer is formed by a silicone elastomer and has the function of protecting the sensitive piezoelectrically active surface of the piezoelectric actuator from damage, contamination, and the effects of moisture and operating substances.

However, the coating of the known piezoelectric component has the disadvantage that, under certain conditions, the heat loss of the piezoelectric actuator may not be dissipated sufficiently well.

### SUMMARY OF THE INVENTION

The piezoelectric component according to the present invention, in which the elastomer is a heat conductive elastomer including a filler which is manufactured on the basis of aluminum oxide, titanium dioxide, boron nitride, aluminum nitride, silicon carbide, and/or preferably silicon dioxide, has the advantage over the related art of improving the dissipation of the heat loss of the ceramic actuator, since increased heat conductivity of the coating may be achieved through the filler. Moreover, additional measures for the electric insulation of the actuator may essentially be dispensed with.

The term coating is to be understood in its broadest sense. The coating may be an elastomer layer directly applied to the actuator, or also an elastomer casting compound in which the actuator is embedded.

The elastomer may be a silicone elastomer which is enriched with the filler. A reactive vulcanized silicone elastomer, such as organopolysiloxane which includes the filler, is used in particular when the coating is implemented in the form of a casting compound. A silicone elastomer is elastic, which permits the mechanical stresses which act upon the ceramic actuator to be kept low.

The coating, which is applied to the surface of the ceramic actuator at least in some areas, protects the ceramic actuator from damage and contamination, as well as from the effects of air moisture and operating substances, and forms an electric insulation. The coating is also applicable to the ceramic actuator in a simple manner.

The piezoelectric component according to the present invention may be used in an injector of a common rail injection system of a diesel engine of a motor vehicle, for example. It is appropriate in this case to use a silicone elastomer as a matrix for the filler which has sufficient elasticity in a temperature range between −40° C. and +150° C. The silicone elastomer is a dimethylsiloxane, for example.

Silicones are three-dimensionally cross-linked systems where distinction may be made between two types of cross-linking, namely addition cross-linking and condensation cross-linking. No breakdown with the formation of byproducts takes place during addition cross-linking, which has an advantageous effect in the present case. Moreover, the elastomer cures independently from the layer thickness.

The elastomer may have a thickness of less than 200 μm.

It is considered appropriate if the filler has a grain size between 0.1 μm and 100 μm, preferably between 1 μm and 15 μm.

In an advantageous embodiment of the piezoelectric component according to the present invention, the proportion of the filler in the elastomer amounts to between 20 weight % and 79 weight %, preferably between 50 weight % and 60 weight %.

In order to increase the adhesive strength of the coating on the ceramic actuator, the elastomer may additionally include a bonding agent which may be a silicone on the basis of a condensation-cross-linked system, e.g., on the basis of alkoxysilanes. The moisture protection of the actuator may be further improved by using the bonding agent in particular.

The bonding agent may be added directly to the elastomer, or, in a separate work step, it may be applied to the ceramic actuator forming the substrate (primer).

The elastomer may be a single-component system or a dual-component system, the single-component system having advantages with regard to the production process in preventing mixing errors and in the logistics.

A characteristic of dual-component systems is the fact that they react as soon as both individual components, i.e., the polymer and the cross-linking agent, are combined. Crosslinking may be accelerated by an increase in temperature. However, cross-linking is basically also possible at room temperature.

In contrast, single-component systems form inhibited systems whose reaction rate is lowered by inhibitors in such a way that adequate storage stability is ensured. On reaching a certain temperature, e.g., a temperature of 100° C., the effect of the inhibitors is affected in such a way that cross-linking takes place.

Cross-linking of the system used is highly temperature-sensitive. Cross-linking occurs for example within 30 minutes at a temperature of 80° C., within 8 minutes at a temperature of 120° C., and within 5 minutes at a temperature of 150° C.

The elastomer is conveniently applied to the ceramic actuator by a dip method, a casting method, or a spray method. The application may take place at room temperature. The temperature is increased for cross-linking of the applied substance, namely to a temperature between for example 80° C. and 150° C. when using a dual-component system, and to a temperature between 100° C. and 150° C. when using a single-component system. Interlacing then occurs within 4 to 39 minutes, depending on the temperature selected.

By using this method, a coating of the ceramic actuator having a layer thickness between 100 μm and 200 μm, possibly less than 100 μm, may be produced.

If the coating represents a casting compound, the ceramic actuator is embedded in the casting compound by introducing the liquid or paste-like material into the volume to be filled in the installation position of the actuator using pressure support or without pressure, such as casting, spraying, or pressing. The volume is preferably filled or partially filled in the upward direction by advantageously introducing the material without pressure, or also in the downward direction by advantageously introducing the material using pressure support. The volume to be filled is predefined by the components of the injector, in particular the ceramic space, a sleeve made of metal, plastic, ceramic or such, which encloses the actuator. Such a procedure ensures stable enclosure of the ceramic, and provides the necessary open volumes, known as expansion volumes.

### BRIEF DESCRIPTION OF THE DRAWING

The Figure shows a schematic illustration of a ceramic actuator having a coating.

### DETAILED DESCRIPTION

A piezoelectric component 10 is illustrated in the Figure, representing a piezoelectric actuator of a fuel injector (not shown in detail) of a common rail fuel injection system of a diesel engine.

Piezoelectric component 10 includes a ceramic actuator 11 which is composed of a stack of piezoelectric ceramic layers, electrode layers being situated between them.

Ceramic actuator 11 is provided with a coating 12, which is applied such that both ends of ceramic actuator 11 remain uncoated.

An elastomer, composed of a silicone elastomer, in particular of dimethylsiloxane, forms coating 12, a filler, manufactured based on silicon oxide, being added to it. The filler has a grain size of approximately 10 μm. The proportion of the filler to the elastomer amounts to approximately 55 weight % in this case.

In the selected example, coating 12 has a layer thickness of approximately 150 μm.

Coating 12 has adequately high heat conductivity so that heat losses of ceramic actuator 11 may be properly dissipated.

What is claimed is:

1. A piezoelectric component comprising:
a ceramic actuator having a coating made of a heat conductive elastomer, which includes a filler manufactured based on at least one of aluminum dioxide, titanium dioxide, boron nitrite, aluminum nitride, silicon carbide and silicon dioxide.

2. The piezoelectric component according to claim 1, wherein the filler is manufactured based on silicon dioxide.

3. The piezoelectric component according to claim 1, wherein the filler has a grain size of between 0.1 μm and 100 μm.

4. The piezoelectric component according to claim 3, wherein the grain size is between 1 μm and 15 μm.

5. The piezoelectric component according to claim 1, wherein a proportion of the filler in the elastomer amounts to between 20 weight % and 79 weight %.

6. The piezoelectric component according to claim 5, wherein the proportion amounts to between 50 weight % and 60 weight %.

7. The piezoelectric component according to claim 1, wherein the elastomer includes a bonding agent.

8. The piezoelectric component according to claim 1, wherein the coating has a thickness of less than 200 μm.
